(19) United States
(12) Patent Application Publication
(10) Pub. No.: US 2025/0115988 A1
(43) Pub. Date: Apr. 10, 2025

(54) METHOD FOR THE PREPARATION OF A MATERIAL COMPRISING SILICON NANOWIRES AND COPPER

(71) Applicant: ENWIRES, Montbonnot-Saint-Martin (FR)

(72) Inventors: Florian D'ACCRISCIO, Montbonnot-Saint-Martin (FR); Nadège REY, Montbonnot-Saint-Martin (FR)

(21) Appl. No.: 18/730,591

(22) PCT Filed: Jan. 18, 2023
(86) PCT No.: PCT/EP2023/051089

§ 371 Date: Jul. 19, 2024

(30) Foreign Application Priority Data
Jan. 21, 2022 (EP) 22305063.4

(51) Int. Cl. C23C 16/02; C23C 16/24; C23C 16/44; C23C 16/442; H01M 4/04; H01M 4/1395; H01M 4/36; H01M 4/38; H01M 4/62

(52) U.S. Cl. CPC C23C 16/02; C23C 16/24; C23C 16/4417; C23C 16/442; H01M 4/0404; H01M 4/1395; H01M 4/366; H01M 4/386; H01M 4/62

(57) ABSTRACT

A method for the preparation of a composite material comprising at least silicon nanowires and copper, said method comprising the use of a copper halide, preferably copper chloride, as a catalyst for preparing silicon nanowires. The method according to the invention has the advantage of being implemented without any pre-treatment and without any solvent.

The present invention is directed to a method for the growth of silicon nanowires using copper halides as a metallic seed precursor. The method is cheap and robust, and allows the growth of silicon nanowire using in-situ transformation of copper halides to CuₓSi_{y} silicides that favors the growth of Si nanowires. Silicon nanowire-based composites prepared by the method according to the invention could be used in various applications such as nano- and micro-electronics, spintronics, energy conversion and scavenging, sensors or anode material for lithium-ion batteries.

### STATE OF THE ART

Silicon, as high earth abundant element with exceptional characteristics, is one of the centerpieces for many applications. Indeed, Silicon is one of the leading components within solar cells technology^{(1,2)} as well as microelectronics⁽³⁾. Silicon has also shown a low discharge potential and a very high theoretical charge capacity (3579 mA·h·g⁻¹)⁽⁴⁾ that makes it very interesting for a Li-ion battery application. One of the other advantages of Silicon is the possibility to change its morphology via nano-structuration. Indeed, silicon can mainly be found as nanoparticles, nanowires or nanosheets morphologies. The nano-structuration of silicon is known to improve its capacity to withstand mechanical strains occurring during the lithiation/de-lithiation process⁽⁵⁾.

Among these morphologies, silicon nanowires (SiNWs) have attracted a lot of attention for their very high aspect ratio favoring efficient charge transport which is particularly beneficial for their application as anode in Li-ion batteries⁽⁶⁾.

In addition, their electrical conductivity can be easily improved by dopant which can extend their applications to supercapacitors^{(7,8)} and thermo-electrics⁽⁹⁾.

The synthesis of SiNWs is mostly described as a bottom-up production via a vapor-liquid-solid (VLS) mechanism. This mechanism is usually driven using a catalyst, namely a growth seed. More precisely, the VLS manufacturing process mainly focusses on the combination of a substrate, such as silicon wafer (a 2D substrate), silicon or carbon nanoparticles (a 0D substrate) and a metallic seed usually in the form of a thin metallic film or nanoparticles.

Gold is one of the most efficient growth seed due to its chemical stability and its high recombination capacity with silicon. Gold is usually used as thin film or nanoparticles as it allows to tune the SiNWs diameter during the growth process. Gold nanoparticles (Au NPs) are known as one the best seed for Si NWs growth. Indeed, the Au—Si binary phase diagram shows a first eutectic point at 363° C. This low eutectic point allows the reaction to be carried out at relatively low temperature (compared to the melting point of gold around 1100° C.) and to be mostly driven by the temperature decomposition of a silane precursor.

Even though Gold can be used with versatile silicon precursors such as silane or diphenylsilane, the synthesis of Au NPs is mostly performed at a laboratory scale for limited SiNWs quantities. The “in-house” production of AuNPs is time consuming, expensive and could be difficult to scale up. This strategic material would be too expensive to allow economically viable mass production of SiNWs.

Other metals such as Tin, Gallium, Zinc or Cadmium having a low eutectic point with silicon can promote the same VLS mechanism. However, most of these metals present a high vapor pressure above 500° C. (typical temperature for Si NWs production) which makes their application difficult at an industrial scale. In addition, with these metals, the problem of mass production of SiNWs at an industrial scale will remain. Another type of growth seed that can promote VSS mechanism is therefore required.

The growth of Si NWs from the VSS mechanism is driven by the formation of silicide phases. For instance, metals such as Copper, Titanium, Platinium or Nickel, allow the formation of silicide compounds⁽¹⁰⁾. In particular, copper presents a very interesting phase diagram with three possible eutectic points: 467° C., 558° C. and 802° C. These eutectic points allow a versatility in the selection of the silicon precursor and in the form of the seed precursor used during the production of Si NWs.

Hashimi et al.⁽¹³⁾ reported the microwave synthesis of Cu NWs via an alkylamine-mediated approach. Copper (II) chloride and octadecylamine were mixed in deionized water at 65° C. for 1 hour. Then, the solution was mixed with glucose-based solution before being microwaved for reaction at 80-120° C. for 2 to 6 hours to form Cu NWs.

Korte et al.⁽¹⁴⁾ presented the synthesis of Ag NWs via polyol reduction of silver nitrate catalyzed by either Cu (I) or Cu (II) chlorides. Copper chlorides were mixed with ethylene glycol, a solution of PVP/ethylene glycol and a solution of AgNO₃/ethylene glycol in successive steps at 150° C. for 1 hour to form Ag NWs.

In these prior art documents, copper chloride has been respectively used for the synthesis of Copper nanowires (Cu NWs) and Silver nanowires (Ag NWs), but not for the synthesis of Si NWs.

Wen et al.⁽¹¹⁾ reported the copper-seeded Si NWs growth via chemical vapor deposition (CVD) of disilane for the study of the formation of η₃—Cu₃Si phase. A thin film of Cu(0) was deposited in-situ onto Si (111) thin foil by thermal evaporation. The Si NWs growth was controlled by the introduction of helium/disilane gas flow in a temperature ranging from 470 to 550° C. at low pressure for 3 h.

Tuan et al.⁽¹²⁾ described the use of CuS nanocrystals as a catalyst for the synthesis of SiNWs. The reaction is a two-step in-situ reaction: the reaction starts with the in-situ conversion of CuS to Cu metal, then proceeds to the growth of SiNWs via the formation of silicide phase when Cu reacts with monophenylsilane at 500° C., at a pressure of 10.3 MPa for 10 minutes.

U.S. Pat. No. 10,243,207B2 reported the production of silicon nanowires using copper-based colloidal nanoparticles deposited on porous substrates to form the growth base. In particular, the growth seed is produced by colloidal synthesis of Cu nanoparticles followed by deposition, adsorption of copper ions or complexes, and electroless deposition on the substrate. As example, this growth base can react with silicon precursors at 460° C. for 45 minutes under low pressure to form a Si NWs based composite.

US2007/166899 discloses a method for growing silicon nanowires useful for the semiconductor industry, the method comprising steps of forming a copper catalyst particle layer on a top surface of a 2D substrate made from a non-metallic material such as silicon, silicon dioxide, quartz, glass and growing the nanowires on said surface. The method disclosed in US2007/166899 typically allows to deposits 10 μg of silicon per square inch of substrate (Si wafer). However, the production of nanowires for Li-ion batteries requires yields of a much higher order of magnitude.

If these examples prove that copper is an interesting candidate as seed for the growth of Si NWs, these manufacturing process remain expensive, time consuming in the processing and do not really allow a large production of Si NWs.

These prior art documents also show that copper-based compounds are mostly used in solution, and require pre-treatment such as deposition on a substrate before NWs growth is carried out.

Therefore, a robust, safe and economically viable technology for mass production of SiNWs is required to bring this unique and relevant material to several industrial applications, in particular the manufacture of Li-ion batteries.

The present invention describes a method for the growth of silicon nanowires using copper halides, preferably copper chlorides, as growth seeds, the method having the advantage of being implemented without any pre-treatment, in particular annealing or heat treatment, and without any solvent. The method is simple, cost-efficient and robust. It uses in-situ transformation of copper halides, preferably copper chlorides, to copper entities at moderate temperature.

The method according to the invention makes it possible to produce large-scale quantities of nanowires in a one-pot process and in a scalable manner thanks to a particular choice of starting materials, in particular the form and the type of the catalyst and of the growth support. These materials are low-cost materials and do not require further processing, making the process simple and cost-effective.

### SUMMARY OF THE INVENTION

A first object of the invention consists in a method for the preparation of a composite material comprising at least silicon nanowires and copper, comprising at least the following stages:
(A) Introducing into the chamber of a reactor a solid/solid mixture of at least a copper halide CuXₙ, with X being selected from: F, Cl, Br, I, and n being an integer selected from 1 or 2, and a growth support in powder form,
(B) Growing silicon nanowires in the chamber of the reactor, from at least one precursor compound of the silicon nanowires chosen from a silane compound or a mixture of silane compounds, and
(C) recovering the product.

Advantageously, step (A) of the process according to the invention comprises:
(1) solid/solid mixing of at least:
a copper halide CuXₙ, with X being selected from: F, Cl, Br, I, and n being an integer selected from 1 or 2,
a growth support in powder form,
(2) introducing into a chamber of a reactor the mixture obtained at step (1),
Or
(1′) introducing into a chamber of a reactor at least:
a copper halide CuXₙ, with X being selected from: F, Cl, Br, I, and n being an integer selected from 1 or 2,
a growth support in powder form,
(2′) solid/solid mixing the copper halide and the growth support in the chamber of the reactor.

Advantageously, step (B) of the process according to the invention comprises:
(3) introducing, into the chamber of the reactor, at least one precursor compound of the silicon nanowires chosen from a silane compound or a mixture of silane compounds,
(4) decreasing the dioxygen content in the chamber of the reactor,
(5) applying a thermal treatment at a temperature ranging from 200° C. to 900° C.,
wherein the order of steps (3) to (5) can be the recited order or another order.

According to a favourite embodiment, the method according to the invention comprises:
(1) solid/solid mixing of at least:
a copper halide CuXₙ, with X being selected from: F, Cl, Br, I, and n being an integer selected from 1 or 2,
a growth support in powder form,
(2) introducing into a chamber of a reactor the mixture obtained at step (1),
Or
(1′) introducing into a chamber of a reactor at least:
a copper halide CuXₙ, with X being selected from: F, Cl, Br, I, and n being an integer selected from 1 or 2,
a growth support in powder form,
(2′) solid/solid mixing the copper halide and the growth support in the chamber of the reactor,
and
(3) introducing, into the chamber of the reactor, at least one precursor compound of the silicon nanowires chosen from a silane compound or a mixture of silane compounds,
(4) decreasing the dioxygen content in the chamber of the reactor,
(5) applying a thermal treatment at a temperature ranging from 200° C. to 900° C., and
(C) recovering the product,
wherein the order of steps (1) to (5) or (1′) to (5) can be the recited order or another order.

According to these embodiments, step (2) is implemented after step (1) and step (2′) after step (1′).

The invention also relates to a method of making an electrode including a current collector, said method comprising (i) implementing the method disclosed above to prepare a composite material and (ii) covering at least one surface of the current collector with a composition comprising said composite material as an electrode active material.

The invention also relates to a method of making an energy storage device, like a lithium secondary battery, including a cathode, an anode, and a separator disposed between the cathode and the anode, wherein said method comprises implementing the method disclosed above to make at least one of the electrodes, preferably the anode.

According to a first variant, the method for the preparation of the composite material is implemented in a fixed-bed reactor.

According to a second variant, the method for the preparation of the composite material is implemented in the tubular chamber of a tumbler reactor set in motion by a rotating and/or a mixing mechanism.

According to third variant, the method for the preparation of the composite material is implemented in a vertical fluidized bed reactor.

According to a favourite embodiment, the copper halide, is chosen from copper (I) chloride CuCl, copper (II) chloride CuCl₂, and a mixture thereof.

According to a favourite embodiment, the growth support is selected from carbon-based materials and carbonaceous polymers.

Preferably, the carbon-based materials are selected from carbon black nanoparticles, carbonaceous polymer fibers, carbon nanotubes, graphene, graphite, preferably from graphite powders, graphene powders, and carbon powders.

Advantageously, these powders have a mean particle size from 0.01 μm to 100 μm, preferably from 0.01 μm to 50 μm, more preferably from 0.05 μm to 50 μm.

According to another embodiment, the growth support is selected from silicon nanoparticles or silicon microparticles.

According to a favourite embodiment, the precursor compound of the silicon nanowires is silane (SiH₄) or diphenylsilane Si(C₆H₅)₂H₂.

According to a favourite embodiment, the thermal treatment is performed at a temperature ranging from 300° C. to 700° C., preferably from 300° C. to 650° C.

According to a favourite embodiment, the thermal treatment is applied from 1 minute to 10 hours.

According to a favourite embodiment, the method for the preparation of the composite material comprises a post-treatment step in order to transform organics resulting from the precursor compound of the silicon nanowires into carbon materials.

### DETAILED DESCRIPTION

The term “consists essentially of” followed by one or more characteristics, means that may be included in the process or the material of the invention, besides explicitly listed components or steps, components or steps that do not materially affect the properties and characteristics of the invention.

The expression “comprised between X and Y” includes boundaries, unless explicitly stated otherwise. This expression means that the target range includes the X and Y values, and all values from X to Y.

A first object of the invention consists in a method for the production of a composite material comprising silicon nanowires through a chemical vapor deposition (CVD) based process. Said composite material is suitable for use as anode active material in lithium-ion batteries, while other uses are conceivable.

SiNWs composite materials obtained by this method can be used as produced, or can be submitted to post-production treatments.

The present invention relates to a method for the preparation of a silicon-based material. It relates to a process for the preparation of a silicon-based composite material comprising at least nano-structured silicon material, copper, and obtained from the chemical decomposition of a reactive silicon-containing gas species. The method is based on the chemical vapor deposition (CVD) principle. By “composite material”, we refer to a material made of at least two constituent materials with significantly different physical or chemical properties.

The external dimensions of the particles may be measured by any known method and notably by analysis of pictures obtained by scanning electron microscopy (SEM) of the composite material according to the invention.

### The Method for the Preparation of the Composite Material

The invention relates to a method for the preparation of a composite material comprising at least copper and SiNWs, the method comprising at least the steps of:
(A) Introducing into the chamber of a reactor a solid/solid mixture of at least a copper halide CuXₙ, with X being selected from: F, Cl, Br, I, and n being an integer selected from 1 or 2, and a growth support in powder form,
(B) Growing silicon nanowires in the chamber of the reactor, from at least one precursor compound of the silicon nanowires chosen from a silane compound or a mixture of silane compounds, and
(C) recovering the product.

Advantageously, step (A) comprises sub-steps (1) to (2) or sub-steps (1′) to (2′) as herein defined. Advantageously, step (B) comprises sub-steps (3) to (5) as herein defined. In particular, the method according to the invention comprises the following steps:
(1) solid/solid mixing of at least:
a copper halide CuXₙ, with X being selected from: F, Cl, Br, I, and n being an integer selected from 1 or 2,
a growth support in powder form,
(2) introducing into a chamber of a reactor the mixture obtained at step (1),
Or
(1′) introducing into a chamber of a reactor at least:
a copper halide CuXₙ, with X being selected from: F, Cl, Br, I, and n being an integer selected from 1 or 2,
a growth support in powder form,
(2′) solid/solid mixing the copper halide and the growth support in the chamber of the reactor,
(3) introducing, into the chamber of the reactor, at least one precursor compound of the silicon nanowires chosen from a silane compound or a mixture of silane compounds,
(4) decreasing the dioxygen content in the chamber of the reactor,
(5) applying a thermal treatment at a temperature ranging from 200° C. to 900° C., and
(C) recovering the product.

The order of steps (1) to (5) or (1′) to (5) can be the recited order or another order, depending essentially on: the characteristics of the reactor in which the method is implemented, the method for reducing dioxygen content and the state (liquid or gaseous) in which the precursor compound of the silicon nanowires is introduced into the reactor.

For example, the steps (3) and/or (4) and/or (5) can be implemented before the steps (1) and (2) or (1′) and (2′). The steps (1) and (2) or (1′) and (2′) are always in this order. For example, the process according to the invention can be implemented in the following order: (3)-(1)-(2)-(4)-(5)-(C) or (4)-(3)-(1′)-(2′)-(5)-(C) or else (1)-(2)-(4)-(3)-(5)-(C).

According to a first variant, the method is implemented in a fixed-bed reactor.

According to a second variant, the method is implemented in the tubular chamber of a tumbler reactor comprising a rotating and/or a mixing mechanism.

According to a third variant, the method is implemented in a (vertical) fluidized bed reactor.

According to a first embodiment, the reactor is closed during the process.

According to a second embodiment, the reactor is open during the process.

By open reactor is meant the reactor remains open to gas flow during the implementation of the method, especially during the thermal treatment step. By closed reactor is meant the introduction of gaseous species into the reactor is achieved at the beginning of the process and then the reactor is closed to gas flow during the thermal treatment step.

### Process Parameters

Process parameters which are reported here-under are common to all variants of the method (fixed-bed reactors, tumbler reactors with a rotating and/or a mixing mechanism, fluidized bed reactor).

The method according to the invention comprises a step of solid/solid mixing of a copper halide catalyst as defined above and in details here-under and a growth support material.

By “solid/solid mixing”, it is meant the combination and/or the association and/or blending of a copper halide in solid form as raw material, preferably in powder form, with a growth support material in a solid form and in powder form, in order to obtain a material of essentially homogeneous composition. The solid/solid mixing is performed in the absence of any medium or solvent. The nature and characteristics of the copper halide catalyst and the growth support material are detailed here-under.

According to a first variant, the step of mixing the copper halide catalyst and the growth support material is performed prior to their introduction into the chamber of the reactor.

Solid/solid mixing can be performed by any industrial mixing apparatus known to the skilled person such as mixer systems (Turbula®, Cyclomix™, Nautamix) or milling systems. As milling systems, the following systems can be cited: ball-milling, attrition-milling, hammer milling, high energy milling, pin-milling, turbo-milling, fine cutting milling, impact milling, fluidized bed milling, conical screw milling, rotor milling, agitated bead milling, or jet milling.

According to a second variant, the step of mixing the copper halide catalyst and the growth support material is performed in the chamber of the reactor. This variant can be carried out in case of the reactor comprises mixing features appropriate for solid/solid mixing. This can be the case, for example, in a tumbler reactor with a rotating mechanism.

Step (4) consisting in decreasing the dioxygen content in the chamber of the reactor can be performed by different methods: Decreasing the dioxygen content in the chamber of the reactor can be implemented by placing the reactor under vacuum, preferably to a pressure inferior or equal to 10⁻¹ bar (10⁻² MPa).

Alternately, decreasing the dioxygen content in the chamber of the reactor can be performed by washing the chamber of the reactor with an inert gas.

In the context of the invention, the expression “washing the chamber of the reactor with an inert gas” means that an inert gas flow is injected into the chamber of the reactor in order to replace the gas present in the reactor by the injected inert gas.

Preferably, the inert gas is chosen from dinitrogen N₂, Argon Ar, and mixtures thereof.

In case the reactor is closed, preferably, the chamber of the reactor is washed at least twice, more preferably at least 3 times with inert gas.

In case the reactor is open, the inert gas can flow through the chamber of the reactor during all or part of the process.

Preferably, at the end of step (4), the dioxygen content in the chamber of the reactor is inferior or equal to 1% by volume, with respect to the total volume of the chamber of the reactor.

Preferably, the thermal treatment is performed at a temperature ranging from 200 to 900° C., preferably from 300° C. to 700° C., even more preferably from 300° C. to 650° C.

The applicant has surprisingly noted that it is possible to control the Si NWs diameter by varying the reaction temperature. Indeed, the diameter of obtained Si NWs decreases when the applied temperature increases.

Preferably, the thermal treatment is performed under low pressure, atmospheric pressure or pressure ranging from 0.11 to 30 MPa, the pressure parameter being governed by the choice of the type of reactor and the open or closed status of the reactor.

During the process according to the invention, and because of the thermal treatment, the pressure in the reactor may increase, especially in case the reactor is closed. This internal pressure depends on the thermal treatment that is applied and is not necessarily controlled or monitored.

Preferably, in particular in case the reactor is closed during the processing, the thermal treatment is applied from 1 minute to 10 hours, preferably from 1 minute to 2 hours, and more preferably from 1 minute to 30 minutes.

According to a variant embodiment, the process according to the invention comprises a post-treatment step, between steps (5) and (C), in order to transform organics into carbon materials. By “organics” it is meant organic chemical residues resulting from the decomposition of the silicon nanowire precursor, in particular silanes, in particular diphenylsilane. When it is implemented, this step consists essentially of a thermal treatment. Advantageously, this step is performed under inert atmosphere, under a carrier gas atmosphere, like for example N₂, Ar, a mixture of Ar/H₂, at a temperature ranging from 500° C. to 700° C., preferably from 550° C. to 650° C., advantageously around 600° C.

The process according to the invention may comprises an additional step (7) of washing the composite material obtained at the end of step (C).

The composite material obtained at the end of step (C) may be washed with an organic solvent, preferably chosen from: chloroform, ethanol, toluene, acetone, dichloromethane, petroleum ether and mixtures thereof.

Alternately, the composite material obtained at the end of step (C) may be washed with an acid solution.

Preferably, after step (7), the process may further comprise a supplementary step of drying the washed composite material.

Drying is for example performed by placing the composite material into an oven, preferably at a temperature superior or equal to 40° C., more preferably superior or equal to 60° C.

Preferably, the drying step lasts from 15 minutes to 12 hours, more preferably from 2 hours to 10 hours, and even more preferably from 5 hours to 10 hours.

### The Precursor Compound of the Silicon Nanowires

The process according to the invention comprises the introduction into the chamber of the reactor, of at least one precursor compound of the silicon nanowires. By “precursor compound of silicon nanowires”, we refer to a compound capable of forming silicon nanowires by implementing the method according to the invention, especially a compound capable of forming silicon nanowires under CVD process conditions.

This compound can be introduced into the chamber of the reactor as a liquid or as a gas. When the compound is introduced into the chamber of the reactor as a liquid, it is transformed to the gas state in the reactor chamber, by controlling the temperature and the pressure in the chamber of the reactor. When the precursor compound of silicon nanowires is in a gas state, it is designated «reactive silicon-containing gas species».

For example, if the precursor compound of SiNWs is a liquid, like for example diphenylsilane, when the reactor reaches appropriate temperature/pressure parameters, the liquid precursor evaporates to a gas species.

The precursor compound of silicon nanowires can be introduced into the reactor as a gas in mixture with a carrier gas.

If the precursor compound is in the form of a reactive silicon-containing gas species, it can be introduced into the chamber of the reactor in mixture with a carrier gas (forming a reactive silicon-containing gas mixture). For example, SiH₄, a gas at ambient temperature/pressure, can be introduced directly into the chamber of the reactor alone or in mixture with a carrier gas. Alternately, a liquid precursor compound like diphenylsilane, Ph₂SiH₂, can be heated to be transformed to the vapour state in a preliminary stage of the process and then be introduced into the chamber of the reactor as a gas, alone or in mixture with a carrier gas.

Preferably, the precursor compound of silicon nanowires, or «reactive silicon-containing gas species», is a silane compound or a mixture of silane compounds.

For the purpose of the invention, the term “silane compound” refers to compounds of formula (I):

R₁—(SiR₂R₃)ₙ—R₄ (I)
wherein:
n is an integer ranging from 1 to 10, and
R₁, R₂, R₃ and R₄ are independently chosen from hydrogen, C₁-C₁₅ alkyl groups, C₆-C₁₂ aryl groups, C₇-C₂₀ aralkyl groups and chloride.

According to this embodiment, preferably, the silicon-containing gas species is chosen from compounds of formula (I) wherein:
n is an integer ranging from 1 to 5, and
R₁, R₂, R₃ and R₄ are independently chosen from hydrogen, C₁-C₃ alkyl groups, phenyl, and chloride.

Even more preferably, n is an integer ranging from 1 to 3, and R₁, R₂, R₃ and R₄ are independently chosen from hydrogen, methyl, phenyl, and chloride.

According to this embodiment, preferably, the precursor compound of silicon nanowires is chosen from silane, disilane, trisilane, chlorosilane, dichlorosilane, trichlorosilane, dichlorodimethylsilane, phenylsilane, diphenylsilane or triphenylsilane or a mixture thereof.

According to a preferred embodiment, the precursor compound of silicon nanowires is silane (SiH₄) or diphenylsilane Si(C₆H₅)₂H₂. The nature and physical state of the precursor compound of silicon nanowires is selected according to the type of reactor and the other parameters of the method.

### The Reactive Silicon-Containing Gas Mixture

The precursor compound of the silicon nanowires is introduced into the reactor as a gas, or as a liquid which is transformed to a gas in the reactor. The silicon nanowires are obtained from the chemical decomposition at high temperature of a reactive silicon-containing gas species, which may be in mixture with a carrier gas. This mixture is referred to hereinafter as «reactive silicon-containing gas mixture».

By “carrier gas”, we refer to a gas that is chosen from a reducing gas, an inert gas, or a mixture thereof.

Preferably, the reducing gas is hydrogen (H₂).

Preferably, the inert gas is chosen from argon (Ar), nitrogen (N₂), helium (He), or a mixture thereof.

According to a preferred embodiment, the silicon-containing gas mixture is composed of at least 1% by volume of silicon-containing gas species, preferably at least 10% by volume, more preferably at least 50% by volume, still more preferably 100% by volume.

The proportions of silicon-containing gas species and carrier gas can be modulated at different levels at different steps of the process.

### The Catalyst

The process according to the invention comprises the introduction into the chamber of the reactor of a CuXₙ catalyst, with X being a halide selected from the group consisting of: F, Cl, Br and I and n being an integer selected from 1 or 2.

Preferably, the copper halide is selected from copper (I) chloride CuCl, copper (II) chloride CuCl₂ and mixtures thereof.

In the context of the invention “catalyst” or “growth seed” are used synonymously and designate a compound selected from compounds of the formula CuXₙ, with X being a halide selected from the group consisting of: F, Cl, Br and I and n being an integer selected from 1 or 2. The function of the catalyst is to promote the growth of SiNWs.

A solid mixture of the copper halide CuXₙ catalyst and the growth support can be prepared before their introduction into the chamber of the reactor, or, alternately, in the chamber of the reactor.

Preferably, copper halides, especially copper chlorides, are used as raw material, in particular in powder form.

Copper halides as raw material are stable products and allow an easier processing compared to other catalysts. Indeed, copper halides, preferably copper chloride, only require solid/solid mixing with the growth support, whereas the growth medium based on gold nanoparticles requires a solid/liquid preparation followed by an evaporation of solvents.

This step of the process according to the invention can be implemented with any industrial mixing apparatus known to the skilled professional such as mixing, ball-milling, attrition-milling, hammer milling, high energy milling, pin-milling, turbo-milling, fine cutting milling, impact milling, fluidized bed milling, conical screw milling, rotor milling, agitated bead milling, or jet milling. Alternately, this step can be implemented in the chamber of the reactor, in case the chamber is adapted. This step of the process does not take more than 30 minutes and can be made neat without any aqueous or organic solvent.

Preferably, the catalyst and the growth support material are used according to a mass ratio catalyst/growth support ranging from 0.01 to 1, more preferably from 0.02 to 0.5, and still more preferably from 0.05 to 0.15.

The association of the catalyst with the growth support material allows the formation of a plurality of particles growth sites on the surface of the growth support material.

### The Growth Support

The method according to the invention is implemented in presence of a growth support in powder form. For example, the growth support can be a carbon-based material, a silicon-based material, an ITO based material, a carbonaceous polymer.

The growth support can be a 0D, 1D, 2D or 3D material.

For example, 0D materials could be silicon nanoparticles or carbon black nanoparticles.

For example, 1D materials could be carbonaceous polymer fibers or carbon nanotubes.

For example, 2D materials could be a silicon wafer, graphene, or an ITO glass. 2D growth support are essentially of interest for applications in nano and microelectronics. For example, 3D materials could be powders such as silicon microparticles, graphite (natural, artificial or expanded), or fine graphite, or a carbonaceous medium such as a polymer material.

For the purpose of the invention, the term “powder” refers to a growth support in solid form, divided in particles of very small dimensions, in particular having a particles size of from 1 nm to 100 μm, preferably from 50 nm to 50 μm. The term “powder” used herein can encompass all forms of materials as long as they meet the size criteria as defined above, i.e. can be in the form of fibers, agglomerates, flakes, tubes, rods, filaments. The average particle size of the support may be measured by using a laser diffraction method.

Preferably the method according to the invention is implemented with a 0D, 1D, or 3D material.

The silicon-based support may be any material selected from the group consisting of silicon nanoparticles, silicon microparticles, silicon wafers, preferably from silicon nanoparticles and silicon microparticles.

Preferably, silicon nanoparticles have a mean particle size from 1 to 100 nm, more preferably 30-50 nm.

Preferably, silicon microparticles have a mean particle size from 0.1 to 30 μm, advantageously from 1 to 15 μm.

Preferably, silicon wafers have a mean width size from 1 cm to 45 cm, advantageously from 1 to 10 cm. The ITO-based support may be any material selected from the group consisting of ITO glass have a mean width size from 1 cm to 100 cm, advantageously from 1 to 10 cm. Although being described in the present disclosure, silicon wafers are not part of the claimed invention.

The carbon-based support may be any material selected from the group consisting of graphite, graphene, carbon, and more specifically natural graphite, artificial graphite, hard carbon, soft carbon, carbon nanotubes or amorphous carbon, carbon nanofibers, carbon black, expanded graphite, graphene or a mixture of two or more thereof. These materials are generally commercially available in powder form.

In case the growth support is a carbon-based support, it can be under the form of particles, particulate agglomerates, non-agglomerated flakes, or agglomerated flakes.

According to this variant, advantageously, the carbon-based support has a Brunauer-Emmett-Teller (BET) surface ranging from 1 to 100 m²/g, more preferably in the range of 1-70 m²/g, even more preferably in the range of 3-50 m²/g.

According to a favourite embodiment of this variant, the carbon-based material is selected from graphite powder, graphene powder, carbon powder, preferably graphite powder with a mean particle size from 0.01 to 50 μm.

According to another variant, the growth support is a carbonaceous polymer material. The use of a polymer as growth support has been disclosed in WO2021018598.

When the growth support is a carbonaceous polymer material, preferably, the polymer material has a decomposition temperature, determined by thermal gravimetric analysis, superior or equal to 200° C., preferably superior or equal to 300° C., more preferably superior or equal to 400° C., advantageously superior or equal to 500° C.

Advantageously, according to this variant, the polymer material is chosen from fibrous polymer materials of synthetic or natural origin, preferably from fibrous polymer materials of synthetic origin.

More advantageously, according to this variant, the polymer material is chosen from polybenzothiazoles, polyamines, polyimides, polyurethanes, polybenzoxazoles, polyamides, polybenzimidazoles and mixtures thereof, preferably chosen from polyamides.

Even more advantageously, according to this variant, the polymer material is poly-paraphenylene terephtalamide, also known as Kevlar®.

In case the growth support is a polymer material, the method according to the invention comprises:
i) preparing a composite material comprising a polymer material and SiNWs according to the method defined above, and
ii) carbonizing the polymer material of the polymeric composite material. Detailed process parameters appropriate to prepare a silicon/polymer composite material and a silicon/carbon composite material have been disclosed in WO2021018598.

As noted in the experimental part, the diameter of the nanowires prepared using copper halides CuXₙ, in particular, copper chlorides, is directly impacted by the temperature of the reaction. Indeed, the diameter of obtained Si NWs decreases when the applied temperature increases.

### Doping Material

According to one embodiment, the process according to the invention comprises the introduction, into the reactor, of at least one doping material.

The term “doping material” is understood to mean, within the meaning of the invention, a material capable of modifying the conductivity properties of the silicon. A doping material within the meaning of the invention is, for example, a material rich in phosphorus, boron or also nitrogen atoms.

Preferentially, and according to this embodiment, the doping material is introduced into the chamber of the reactor by means of a precursor chosen from diphenylphosphine, triphenylborane and di- and triphenylamine. According to a first variant, this introduction is implemented before the growth of SiNWs has started.

According to another variant, the precursor of the doping material is introduced as a gas simultaneously with (and possibly as part of) the reactive silicon-containing gas mixture.

Preferably, the molar proportion of doping material, with respect to the precursor compound of the silicon nanowires, is from 10⁻⁴ molar % to 10 molar %, preferably from 10⁻² molar % to 1 molar %.

### The Reactor

According to a first variant, the method according to the invention is implemented in a fixed-bed reactor.

According to a second variant, the method according to the invention is implemented in the tubular chamber of a tumbler reactor comprising a rotating and/or a mixing mechanism.

According to a third variant, the method according to the invention is implemented in a (vertical) fluidized bed reactor.

### First Variant

According to a first variant, the method according to the invention is implemented in a fixed-bed reactor.

### Characteristics of the Reactor:

The fixed-bed reactor can be an open reactor or a closed reactor.

A reactor which can be used to implement the method according to the invention is disclosed for example in WO2019020938. In this document, it is used in the “closed reactor” mode.

According to an alternate embodiment, an open fixed bed reactor is used to implement the method according to the invention. Such a reactor is for example the tubular chamber of a tumbler reactor which is used in a static mode (without rotation or mixing).

### Parameters:

Preferably, according to this first variant, the method according to the invention comprises at least the following steps:
(1) solid/solid mixing of at least:
a copper halide CuXₙ, with X being selected from: F, Cl, Br, I, and n being an integer selected from 1 or 2,
a growth support in powder form,
(2) introducing into a chamber of the reactor of the mixture obtained at step (1),
(3) introducing, into the chamber of the reactor, at least one precursor compound of the silicon nanowires chosen from a silane compound or a mixture of silane compounds,
(4) decreasing the dioxygen content in the chamber of the reactor,
(5) applying a thermal treatment at a temperature ranging from 200° C. to 900° C., and
(C) recovering the product.

According to this first variant, in case the reactor is closed, decreasing the dioxygen content in the chamber of the reactor can be performed by placing the reactor under vacuum, preferably to a pressure inferior or equal to 10⁻¹ bar (10⁻² MPa).

Alternately, decreasing the dioxygen content in the chamber of the reactor can be performed by washing the chamber of the reactor with an inert gas.

In the context of the invention, the expression “washing the chamber of the reactor with an inert gas” means that an inert gas flow is injected into the chamber of the reactor in order to replace the gas present in the reactor by the injected inert gas.

Preferably, the inert gas is chosen from dinitrogen N₂, Argon Ar, and mixtures thereof. In case the reactor is closed, preferably, the chamber of the reactor is washed at least twice, more preferably at least 3 times with inert gas. In case the reactor is open, the inert gas can flow through the chamber of the reactor during all or part of the process.

Preferably, at the end of step (4), the dioxygen content in the chamber of the reactor is inferior or equal to 1% by volume, with respect to the total volume of the chamber of the reactor.

According to the first embodiment of this variant, when the reactor is closed, generally the precursor compound of the silicon nanowires is introduced into the reactor as a liquid.

According to the first embodiment of this variant, when the reactor is closed, the copper halide catalyst, the growth support, and the precursor compound of the silicon nanowires can be introduced into the reactor in the form of a mixture.

According to the first embodiment of this variant, when the reactor is closed, preferably the reactor comprises at least two charging zones, a first zone which makes it possible to receive the precursor compound of the silicon nanowires and a second zone which makes it possible to receive the mixture of the growth support and the copper halide catalyst.

According to a first alternative form, the first charging zone and the second charging zone are located at the same level in the chamber of the reactor.

According to a preferred alternative form, the second charging zone is raised with respect to the first charging zone.

According to a second embodiment of this variant, when the reactor is open, generally the precursor compound of the silicon nanowires is introduced into the reactor as a gas in mixture with an inert gas, designated “reactive silicon-containing gas mixture”.

### Second Variant

According to a second variant, the method according to the invention is implemented in the tubular chamber of a tumbler reactor comprising a rotating and/or a mixing mechanism. Characteristics of the reactor:

The tumbler reactor here-above mentioned is composed of at least a tubular chamber, heated by a furnace, in which the growth support material and the copper halide catalyst can be loaded, either as separate material or as a mixture. The reactor integrates a rotating mechanism and/or a mixing mechanism. The tubular chamber longitudinal axis is horizontal or can be tilted to make an angle with the horizontal axis up to 20°. The reactor further comprises a product feeding system and a product discharge system, allowing a semi-continuous production of silicon-copper composite material. The tumbler reactor comprises a reactor pressure control device, like for example a needle valve, or a pressure controller.

A typical mechanical tumbler reactor is a Lödige's type fluidized-bed reactor, where fluidization is generated by the rotation of a horizontal axis helix in the tubular chamber.

Another typical mechanical tumbler reactor comprises a rotating tubular chamber where fluidization is generated by the rotation of the tubular chamber around its longitudinal axis.

### Parameters:

This variant is of particular interest as fluidization mechanically generated by the reactor is beneficial to the contact between the growth support and the silicon comprising reactive gas species. This variant is also of particular interest since it permits the direct introduction of the catalyst and the growth support and their mixing in the chamber of the reactor.

According to this variant, preferably the precursor compound of the silicon nanowires is introduced into the reactor as a gas.

### Steps of the Process:

According to this variant, the method according to the invention advantageously comprises:
(1′A) introducing into the tubular chamber of the reactor at least:
a copper halide CuXₙ, with X being selected from: F, Cl, Br, I, and n being an integer selected from 1 or 2,
a growth support in powder form,
(2′A) rotating the tubular chamber and/or starting the mixing mechanism of the copper halide and the growth support,
(2′B) heating the tubular chamber under carrier gas flow,
(3) introducing a reactive silicon-containing gas mixture into the tubular chamber,
(4) controlling the pressure in the chamber of the reactor with the gas mixture flow,
(5) applying a thermal treatment at a temperature ranging from 200° C. to 900° C., under reactive silicon-containing gas mixture flow, in the tubular chamber under rotation and/or mixing,
(C) recovering the obtained product,

According to this variant, most steps have to be accomplished according to this order, however, the rotation and/or mixing at step (2′A) can start before or after step (2′B).

According to this variant, the thermal treatment of step (5) is applied at low pressure (lower than atmospheric), or at atmospheric pressure or at a pressure superior to atmospheric.

Preferably, when the reactor is a tumbler reactor comprising a rotating and/or a mixing mechanism, the thermal treatment of step (5) is applied at atmospheric pressure.

### Third Variant

According to a third variant, the method according to the invention is implemented in a vertical fluidized bed reactor.

### Characteristics of the Reactor:

The vertical fluidized-bed reactor generally consists in a vertical cylindrical stainless-steel column. The bottom of the column presents a perforated steel plate supporting the powder and providing a homogeneous gas distribution, and a flange which is cooled by water to avoid any silane premature decomposition. At the exit, a high-performance filtration cartridge allows collecting the elutriated particles. The reactor is externally heated by a two-zone electrical furnace and its wall temperatures are controlled by at least two thermo-couples connected to regulators. Several thermocouples are also placed along the reactor to monitor the axial profile of temperature. Pressure sensors allow to control/monitor the pressure inside the reactor. Flow meters allow to control the different gas flows inside the reactor through the powder.

### Parameters:

In a vertical fluidized bed reactor, the method according to the invention can be performed at atmospheric pressure or under a pressure slightly superior to atmospheric. For example, a pressure superior or equal to 1.3·10⁵ Pa is convenient.

Preferably, the applied temperature ranges from 300° C. to 650° C.

According to this variant, preferably the precursor compound of the silicon nanowires is introduced into the reactor as a gas.

According to this variant, both the catalyst and the growth support are in powder form.

### Steps of the Process:

(1) introducing into the tubular chamber at least the copper halide catalyst, preferably the copper chloride catalyst, and the growth support,
(2) solid/solid mixing of the copper halide catalyst and the growth support powders,
(4) Sealing test: a sealing test is performed on the reactor with Nitrogen (1 slm). The sealing test is valid when the pressure stays stable after 1 minute.
(4′) Fluidization of the powder(s): The fluidization is performed using a neutral gas and its flow rate is regularly increased until reaching the desired flow rate. For example, its flow rate is increased of 0.5 slm every two minutes until reaching the desired flow rate.
(5) Applying a thermal treatment: Then, the heating system of the furnace and the cooling system of the flange at the bottom of the bed are started.
(3) After the fluidized bed has reached the isothermal stabilization, the reactive gas is introduced into the chamber.
(C) Recovering the product: At the end of the reaction, the reactor is cooled down before collecting the obtained product. For example, the reactor is cooled to 150° C. or below before the product is recovered.

Most steps have to be accomplished according to this order.

Such a method is disclosed for example in WO2011/137446 (A2).

### Material Composition:

The above disclosed method gives access to a composite material comprising silicon nanowires and copper entities.

The above disclosed method gives access to a composite material comprising, preferably consisting essentially of: the growth support, silicon nanowires and copper entities.

According to another embodiment, the above disclosed method gives access to a composite material consisting essentially of: silicon nanowires and copper entities.

Advantageously, in the composite obtained, Si content is superior to 5%, preferably superior to 20%, by weight of silicon, with regards to the total weight of the material.

The term “copper entities” or “copper” as used herein is understood to mean, within the meaning of the invention, compounds resulting from the reaction of copper halides, especially copper chlorides, with the silicon precursor, especially silane gas during the growth of the silicon nanowires as well as remaining unreacted copper halides. As copper entities, CuₓSi_{y} silicides may be particularly mentioned. The composite material preferably comprises copper entities in amounts ranging from 0.1% to 10% by weight with regards to the total weight of the material, preferably ranging from 0.1% to 5%.

By remaining unreacted copper halides, we refer to the fact that not all introduced copper halides react with silicon precursor during the process.

The material may comprise halides, especially chloride, as traces.

Traces of halide, especially chloride, can be found in the composite. Typical values are below 1% by weight of halide, especially chloride, with regards to the total weight of the material, preferably below 0.01%.

Advantageously, the silicon material, resulting from chemical vapor decomposition of the precursor compound of silicon nanowires, is under the form of wires. Other morphologies can be present such as worms, rods or filaments. According to a preferred embodiment, the silicon material, in particular resulting from chemical vapor decomposition of the silicon containing gas species as described above, is a mixture of nanowires and nanoparticles. Such an embodiment corresponds for example to the case wherein SiH₄ is used as the precursor compound of SiNWs.

The term “nanowire” is understood to mean, within the meaning of the invention, an elongated element, the shape of which is similar to that of a wire and the diameter of which is nanometric.

Preferably, silicon nanowires have a diameter ranging from 1 nm to 250 nm, more preferentially ranging from 10 nm to 200 nm and more preferentially still ranging from 30 nm to 180 nm.

The size of the silicon material may be measured by several techniques well known by the skilled person such as for example by analysis of pictures obtained by scanning electron microscopy (SEM) from one or more samples of the carbon-silicon composite material.

Advantageously, silicon, preferably silicon nanowires, represents from 1% to 70% by weight of the silicon-based composite material, preferably from 10% to 70% by weight, more preferably from 20% to 70% by weight, even more preferably from 30% to 70% by weight, advantageously from 50% to 70% by weight.

Advantageously, the silicon-based composite material is preferably obtained in the form of a powder.

### Uses of the Carbon-Silicon Composite Material

The silicon composite material according to the invention may be used as an anode active material and for the manufacture of a lithium-ion battery.

An electrode including a current collector is prepared by a preparation method classically used in the art. For example, the anode active material consisting in the silicon composite material of the present invention is mixed with a binder, a solvent, and a conductive agent. If necessary, a dispersant may be added. The mixture is stirred to prepare a slurry. Then, the current collector is coated with the slurry and pressed to prepare the anode.

Various types of binder polymers may be used as the binder in the present invention, such as a polyvinylidene fluoride-hexafluoropropylene copolymer (PVDF-co-HEP), polyvinylidene fluoride, polyacrylonitrile, and polymethylmethacrylate.

The electrode may be used to manufacture a lithium secondary battery including a separator and an electrolyte solution which are typically used in the art and disposed between the cathode and the anode.

### BRIEF DESCRIPTION OF THE DRAWINGS

FIG. 1 is a photograph obtained by scanning electron microscopy (SEM) of Si nanowires/copper CuCl₂/KS4 graphite composite at low magnification (example 1).

FIG. 2 is a photograph obtained by scanning electron microscopy (SEM) of Si nanowires/copper CuCl₂/KS4 graphite composite at high magnification (example 1).

FIG. 3 is a graphic representing the potential profile of the cell prepared from Si nanowires/copper CuCl₂/KS4 graphite composite (example 1): The x-axis represents the capacity of the cell in mA·h, and the y-axis represents the potential of the cell in V.

FIG. 4 is a photograph obtained by scanning electron microscopy (SEM) at low magnification of a Si nanowires/copper CuCl₂/SFG75 graphite composite obtained by treatment with SiH₄ at 550° C. (example 2).

FIG. 5 is a photograph obtained by scanning electron microscopy (SEM) at high magnification of a Si nanowires/copper CuCl₂/SFG75 graphite composite obtained by treatment with SiH₄ at 550° C. (example 2).

FIG. 6 is a graphic representing the potential profile of the cell prepared from Si nanowires/copper CuCl₂/SFG75 graphite composite obtained by treatment with SiH₄ at 550° C. (example 2): The x-axis represents the capacity of the cell in mA·h, and the y-axis represents the potential of the cell in V.

FIG. 7 is a photograph obtained by scanning electron microscopy (SEM) at low magnification of a Si nanowires/copper CuCl₂/SFG75 graphite composite obtained by treatment with SiH₄ at 500° C. (example 3).

FIG. 8 is a photograph obtained by scanning electron microscopy (SEM) at high magnification of a Si nanowires/copper CuCl₂/SFG75 graphite composite obtained by treatment with SiH₄ at 500° C. (example 3).

FIG. 9 is a graphic representing the potential profile of the cell prepared from Si nanowires/copper CuCl₂/SFG75 graphite composite obtained by treatment with SiH₄ at 500° C. (example 3): The x-axis represents the capacity of the cell in mA·h, and the y-axis represents the potential of the cell in V.

FIG. 10 is a photograph obtained by scanning electron microscopy (SEM) at low magnification of a Si nanowires/copper CuCl₂/SLP50 graphite composite obtained by treatment with SiH₄ at 550° C. (example 4).

FIG. 11 is a photograph obtained by scanning electron microscopy (SEM) at high magnification of a Si nanowires/copper CuCl₂/SLP50 graphite composite obtained by treatment with SiH₄ at 550° C. (example 4).

FIG. 12 is a graphic representing the potential profile of the cell prepared from Si nanowires/copper CuCl₂/SLP50 graphite composite obtained by treatment with SiH₄ at 550° C. (example 4): The x-axis represents the capacity of the cell in mA·h, and the y-axis represents the potential of the cell in V.

FIG. 13 is a photograph obtained by scanning electron microscopy (SEM) at low magnification of a Si nanowires/copper CuCl₂/SLP50 graphite composite obtained by treatment with SiH₄ at 500° C. (example 5).

FIG. 14 is a photograph obtained by scanning electron microscopy (SEM) at high magnification of a Si nanowires/copper CuCl₂/SLP50 graphite composite obtained by treatment with SiH₄ at 500° C. (example 5).

FIG. 15 is a graphic representing the potential profile of the cell prepared from Si nanowires/copper CuCl₂/SLP50 graphite composite obtained by treatment with SiH₄ at 500° C. (example 5): The x-axis represents the capacity of the cell in mA·h, and the y-axis represents the potential of the cell in V.

FIG. 16 is a photograph obtained by scanning electron microscopy (SEM) at low magnification of a Si nanowires/copper CuCl₂/KS4 graphite composite obtained by treatment with SiH₄ at 550° C. (example 6).

FIG. 17 is a photograph obtained by scanning electron microscopy (SEM) at high magnification of a Si nanowires/copper CuCl₂/KS4 graphite composite obtained by treatment with SiH₄ at 550° C. (example 6).

FIG. 18 is a graphic representing the potential profile of the cell prepared from Si nanowires/copper CuCl₂/KS4 graphite composite obtained by treatment with SiH₄ at 550° C. (example 6): The x-axis represents the capacity of the cell in mA·h, and the y-axis represents the potential of the cell in V.

FIG. 19 is a photograph obtained by scanning electron microscopy (SEM) at low magnification of a Si nanowires/copper CuCl/SFG75 graphite composite obtained by treatment with SiH₄ at 550° C. (example 7).

FIG. 20 is a photograph obtained by scanning electron microscopy (SEM) at high magnification of a Si nanowires/copper CuCl/SFG75 graphite composite obtained by treatment with SiH₄ at 550° C. (example 7).

FIG. 21 is a graphic representing the potential profile of the cell prepared from Si nanowires/copper CuCl/SFG75 graphite composite obtained by treatment with SiH₄ at 550° C. (example 7): The x-axis represents the capacity of the cell in mA·h, and the y-axis represents the potential of the cell in V.

### EXPERIMENTAL PART

In the following examples, and unless otherwise indicated, the contents and percentages are given in mass.

### Material

Reactor (fixed bed): stainless steel reactor (intern volume=1 L, diameter=100 mm, height=125 mm).
Ball-milling apparatus: Model PM100, commercialized by the company Retsch.
Turbula® apparatus: Model T2F, commercialized by the company Wab.
silicon precursor: diphenylsilane Si(C₆H₅)₂H₂, commercialized by the company Sigma-Aldrich (CAS Number: 775-12-2), SiH₄ commercialized by Messer.
catalyst: CuCl and CuCl₂ commercialized by the company Alfa Aeser.
graphite growth support: SFG75 graphite (SSA=3.5 m²/g), KS4 graphite, (SSA=24.48 m²/g) and SLP50 graphite (SSA=4.97 m²/g) are commercialized by the company Imerys.
conductive fillers: graphite powder commercialized by the company Imerys under the name C-NERGY™ Actilion GHDR-15-4 and C-NERGY™ SFG15 L.
carbon black, commercialized by the company Imerys under the commercial reference Timcal C-NERGY C₆₅ (CAS Number: 1333-86-4).
sodium carboxymethylcellulose (CMC) commercialized by the company Alfa-Aesar (CAS Number: 9004-32-4).
styrene-butadiene rubber (SBR) commercialized by the company MTI Corporation (CAS Number: 9003-55-8).
electrolyte: lithium hexaflurorophosphate LiPF₆ (1M) dissolved in a mixture of ethylene carbonate (EC) and diethylcarbonate (DEC) (1:1 in volume) comprising 10% by weight of fluoroethylene carbonate (FEC) and 2% by weight of vinylene carbonate (additive), commercialized by the company Solvionic.

### Example 1: Synthesis of KS4 Graphite/Copper CuCl₂/Si NWs Composite Material (M1)

### a) Mixing KS4 Graphite and CuCl₂ as Pre-Catalyst Material

3 g of graphite KS4 is combined to 0.355 g of CuCl₂ and introduced in a steel bowl of the ball-milling apparatus. Then, 40 g of 3 mm steel balls are introduced in the bowl before being tightly closed. The powders are mixed for 10 minutes 30 seconds at 400 rpm.

The pre-catalyst material is recovered by extracting the balls with a sieve.

### b) Growth of the Silicon Nanowires (Process 1)

The material obtained at the end of step a) is placed on a glass cup inside the fixed-bed reactor. 50 mL of diphenylsilane, Ph₂SiH₂, are then poured at the bottom of the reactor. After sealing the reactor, gas lines and temperature heating elements are connected to the reactor. The reactor is then put under vacuum and purged several times with N₂ to decrease the oxygen level. Subsequently, the reactor is heated up by means of an electric resistance placed in contact with the exterior surface of the reactor. The heating cycle is as follows: a heating ramp of 30 minutes from 20° C. to 430° C., a plateau of 60 minutes at 430° C., the heating is stopped and then the reactor is cooled down to room temperature. The reactor is finally opened to recover the composite material.

### c) Post-Treatment of the Graphite/Copper/Silicon Composite Material (Process 2)

The carbonization of the organics resulting from Ph₂SiH₂ decomposition is performed by thermal treatment.

The composite material obtained at the end of Process 1 is placed in a crucible which is then introduced in a horizontal quartz tube furnace. The inlet of the furnace is connected to argon Ar and dihydrogen H₂ gas lines with controlled amounts in a ratio of 97.5:2.5 (v/v) that are continuously flowed over the material. Thermal treatments are performed with a heating ramp of 6° C./min up to a temperature equal to 600° C. for a duration of 2 h, followed by natural cooling. The furnace is finally opened to recover the composite M1.

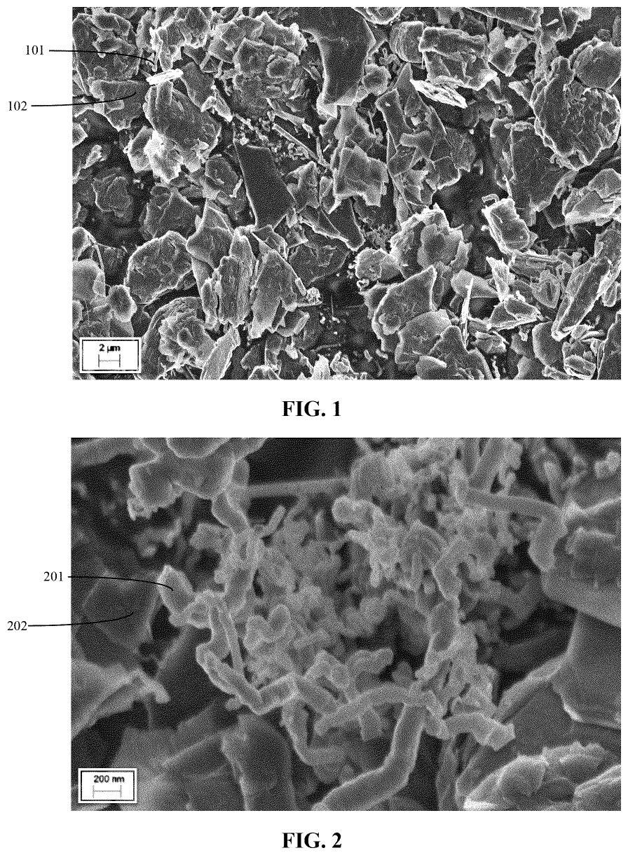

FIGS. 1 and 2 are SEM micrographs of the Si nanowires/copper CuCl₂/KS4 graphite composite M1. FIG. 1 shows Si NWs 101 having a mean diameter of 190 nm onto the surface of the KS4 graphite 102. FIG. 2 shows large kinked and frizzed Si NWs 201 onto the surface of the KS4 graphite 202.

### Example 2: Synthesis of SFG75 Graphite/Copper CuCl₂/Si NWs Composite Material (M2)

### a) Mixing SFG75 Graphite and CuCl₂ as Pre-Catalyst Material

12.5 g of SFG75 graphite is combined to 1.48 g of CuCl₂ and introduced in Turbula® T2F mixer for 15 minutes.

### b) Growth of the Silicon Nanowires (Process 1)

The pre-catalyst material obtained at the end of step a) is placed homogeneously in a mullite tube inside the fixed-bed reactor.

After connecting the gas line to the reactor and closing the heating chamber, the quartz tube is flushed with N₂ at 5 slm for several minutes to decrease the oxygen level. Subsequently, the reactor is heated up by means of the heating device placed in contact with the exterior surface of the quartz tube. The heating and gas injection cycles are as follows: a heating ramp of 1 h from 20° C. to 650° C. under 5 slm Ar/H₂ 2.5% gas flow rate, a plateau of 2.15 hours at 550° C. under 5 slm N₂/SiH₄ 0.9% (L/min), heating is stopped and then the reactor is cooled down to room temperature under 5 slm N₂ gas flow rate. The reactor is finally opened to recover the composite material.

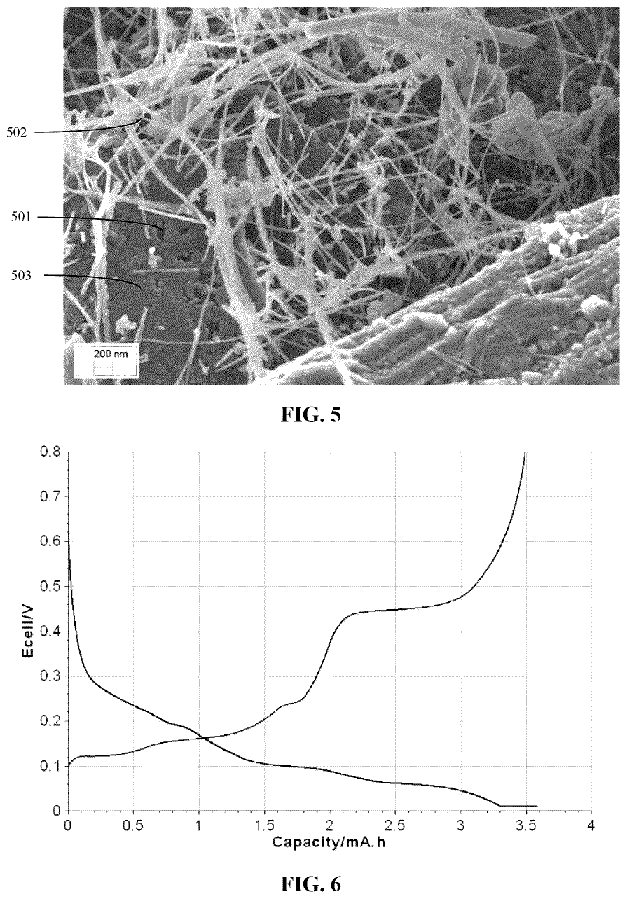

FIGS. 4 and 5 show SEM micrographs of the Si nanowires/copper CuCl₂/SFG75 graphite composite M2. The figures show long and straight Si NWs having a mean diameter of 40 nm (402 and 502) and Si nanoparticles (503) on the surface of SFG75 graphite 401 and 501.

### Example 3: Synthesis of SFG75 Graphite/Copper CuCl₂/Si NWs Composite Material (M3) 500° C.

### a) Mixing SFG75 Graphite and CuCl₂ as Pre-Catalyst Material

12.5 g of SFG75 graphite is combined to 1.48 g of CuCl₂ and introduced in Turbula® T2F mixer for 15 minutes.

### b) Growth of the Silicon Nanowires (Process 1)

The pre-catalyst material obtained at the end of step a) is placed homogeneously in a mullite tube inside the fixed-bed reactor.

After connecting the gas line to the reactor and closing the heating chamber, the quartz tube is flushed with N₂ at 5 slm for several minutes to decrease the oxygen level. Subsequently, the reactor is heated up by means of the heating device placed in contact with the exterior surface of the quartz tube. The heating and gas injection cycles are as follows: a heating ramp of 1 h from 20° C. to 650° C. under 5 slm Ar/H₂ 2.5% gas flow rate, a plateau of 2.15 hours at 500° C. under 5 slm N₂/SiH₄ 0.9% (L/min), heating is stopped and then the reactor is cooled down to room temperature under 5 slm N₂ gas flow rate. The reactor is finally opened to recover the composite material.

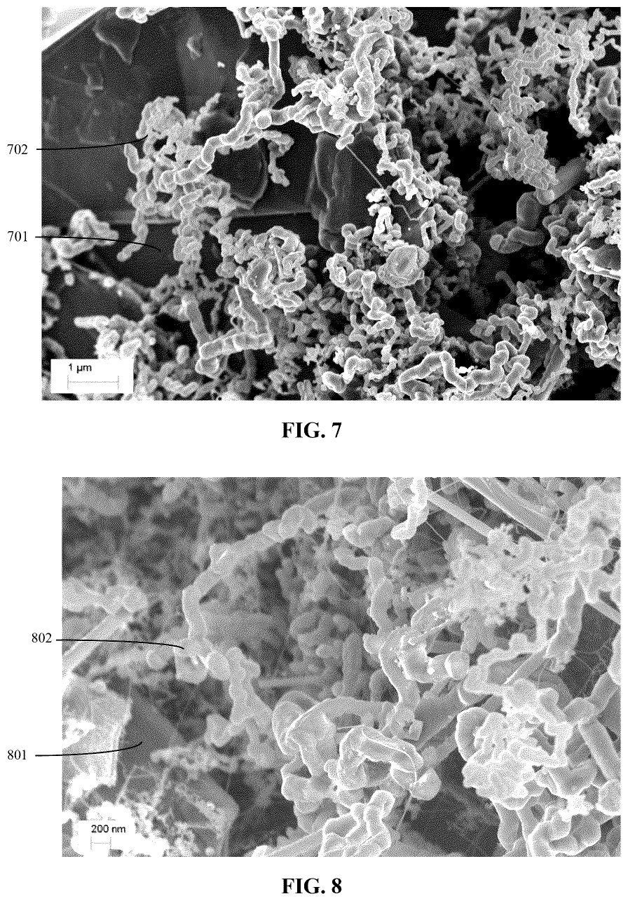

FIGS. 7 and 8 show SEM micrograph of the obtained Si nanowires/copper CuCl₂/SFG75 graphite composite M3. Kinked and short SiNWs (702 and 802) having a mean diameter of 176 nm on the surface of SFG75 graphite 701 and 801 are obtained.

### Example 4: Synthesis of SLP50 Graphite/Copper CuCl₂/Si NWs Composite Material (M4) 550° C.

### a) Mixing SLP50 Graphite and CuCl₂ as Pre-Catalyst Material

12.5 g of SLP50 graphite is combined to 1.48 g of CuCl₂ and introduced in Turbula® T2F mixer for 15 minutes.

### b) Growth of the Silicon Nanowires (Process 1)

The pre-catalyst material obtained at the end of step a) is placed homogeneously in a mullite tube inside the fixed-bed reactor.

After connecting the gas line to the reactor and closing the heating chamber, the quartz tube is flushed with N₂ at 5 slm for several minutes to decrease the oxygen level. Subsequently, the reactor is heated up by means of the heating device placed in contact with the exterior surface of the quartz tube. The heating and gas injection cycles are as follows: a heating ramp of 1 h from 20° C. to 650° C. under 5 slm Ar/H₂ 2.5% gas flow rate, a plateau of 2.15 hours at 550° C. under 5 slm N₂/SiH₄ 0.9% (L/min), heating is stopped and then the reactor is cooled down to room temperature under 5 slm N₂ gas flow rate. The reactor is finally opened to recover the composite material.

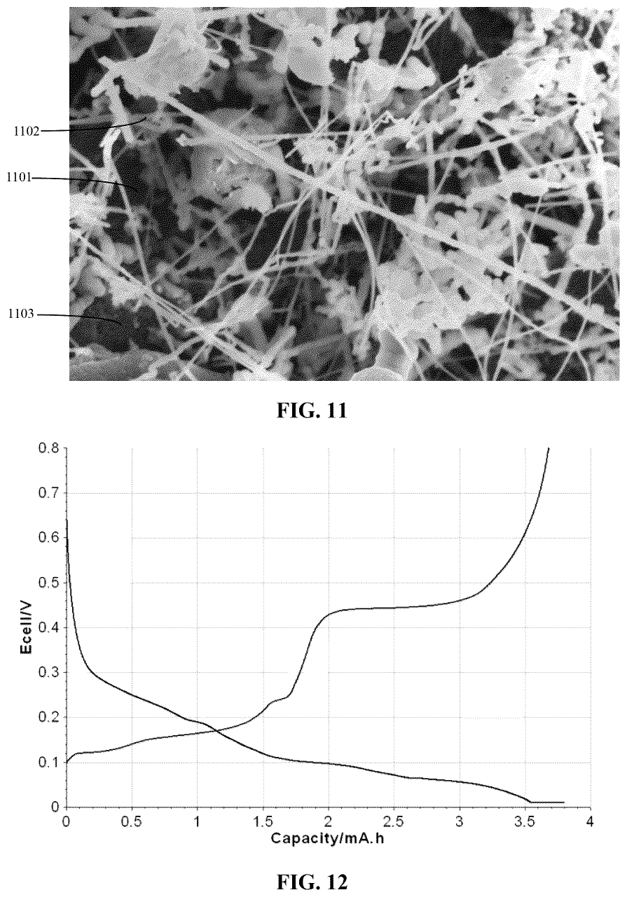

FIGS. 10 and 11 show SEM micrograph of the obtained Si nanowires/copper CuCl₂/SLP50 graphite composite M4. A mixture of kinked and short SiNWs 1103 and straight and long SiNWs 1002 having a mean diameter of 68 nm on the surface of the SLP50 graphite 1001 and 1101 is obtained.

### Example 5: Synthesis of SLP50 Graphite/Copper CuCl₂/Si NWs Composite Material (M5) 500° C.

### a) Mixing SLP50 Graphite and CuCl₂ as Pre-Catalyst Material

12.5 g of SLP50 graphite is combined to 1.48 g of CuCl₂ and introduced in Turbula® T2F mixer for 15 minutes.

### b) Growth of the Silicon Nanowires (Process 1)

The pre-catalyst material obtained at the end of step a) is placed homogeneously in a mullite tube inside the fixed-bed reactor.

After connecting the gas line to the reactor and closing the heating chamber, the quartz tube is flushed with N₂ at 5 slm for several minutes to decrease the oxygen level. Subsequently, the reactor is heated up by means of the heating device placed in contact with the exterior surface of the quartz tube. The heating and gas injection cycles are as follows: a heating ramp of 1 h from 20° C. to 650° C. under 5 slm Ar/H₂ 2.5% gas flow rate, a plateau of 2.15 hours at 500° C. under 5 slm N₂/SiH₄ 0.9% (L/min), heating is stopped and then the reactor is cooled down to room temperature under 5 slm N₂ gas flow rate. The reactor is finally opened to recover the composite material.

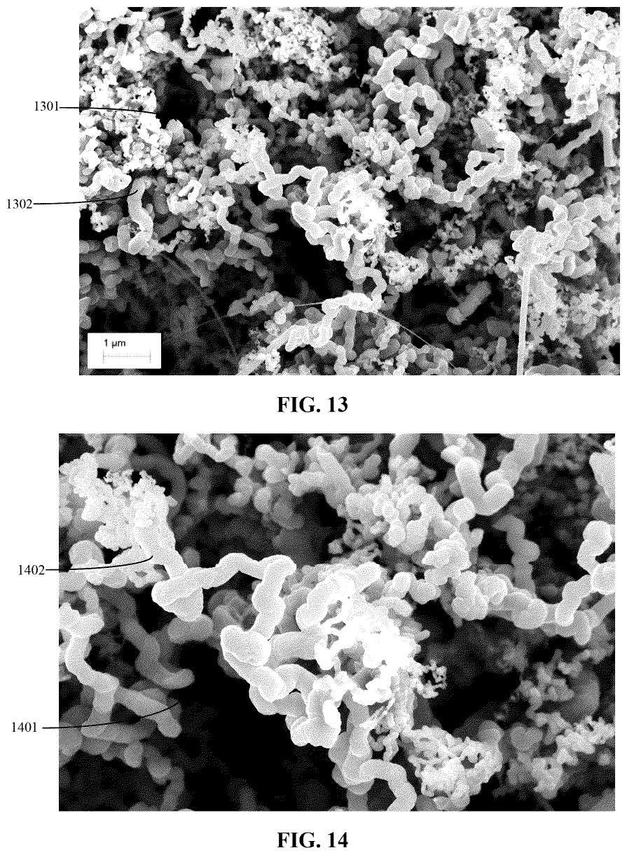

FIGS. 13 and 14 show SEM micrographs of the Si nanowires/copper CuCl₂/SLP50 graphite composite material M5. Kinked and short Si NWs 1302 and 1402 having a mean diameter of 176 nm on the surface of the SLP50 graphite 1301 and 1401.

### Example 6: Synthesis of KS4 Graphite/Copper CuCl₂/Si NWs Composite Material (M6) 550° C.

### a) Mixing KS4 Graphite and CuCl₂ as Pre-Catalyst Material

12.5 g of KS4 graphite is combined to 1.48 g of CuCl₂ and introduced in Turbula® T2F mixer for 15 minutes.

### b) Growth of the Silicon Nanowires (Process 1)

The pre-catalyst material obtained at the end of step a) is placed homogeneously in a mullite tube inside the fixed-bed reactor.

After connecting the gas line to the reactor and closing the heating chamber, the quartz tube is flushed with N₂ at 5 slm for several minutes to decrease the oxygen level. Subsequently, the reactor is heated up by means of the heating device placed in contact with the exterior surface of the quartz tube. The heating and gas injection cycles are as follows: a heating ramp of 1 h from 20° C. to 650° C. under 5 slm Ar/H₂ 2.5% gas flow rate, a plateau of 2.15 hours at 550° C. under 5 slm N₂/SiH₄ 0.9% (L/min), heating is stopped and then the reactor is cooled down to room temperature under 5 slm N₂ gas flow rate. The reactor is finally opened to recover the composite material.

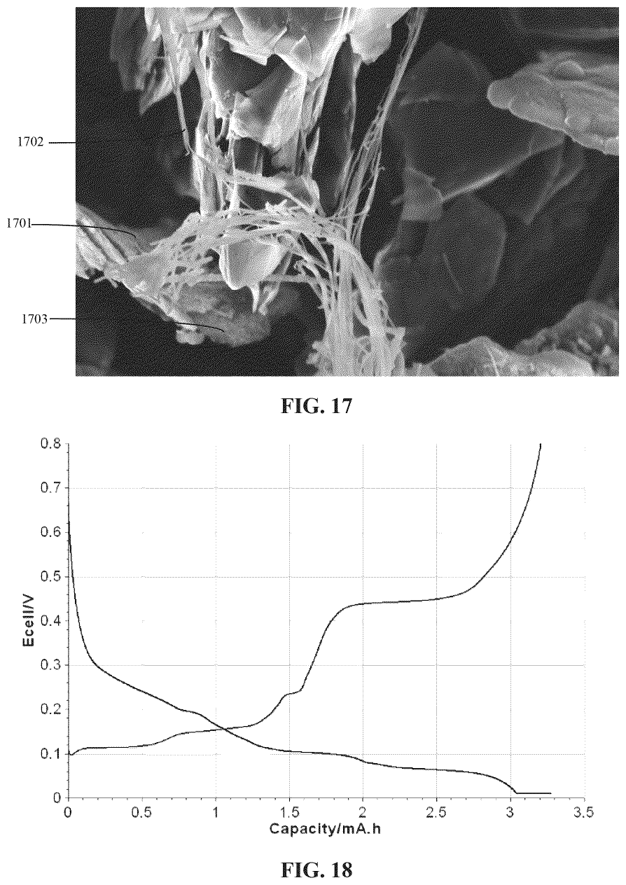

FIGS. 16 and 17 show SEM micrographs of the Si nanowires/copper CuCl₂/KS4 graphite composite M6 obtained having a mean diameter of 20 nm on KS4.

The Figures show long and straight Si NWs 1602 and 1702 and aggregation of nanoparticles 1603 and 1703 caught on the surface of the KS4 graphite 1601 and 1701.

### Example 7: Synthesis of SFG75 Graphite/Copper CuCl/Si NWs Composite Material (M7) 550° C.

### a) Mixing SFG75 Graphite and CuCl as Pre-Catalyst Material

12.5 g of SFG75 graphite is combined to 1.09 g of CuCl and introduced in Turbula® T2F mixer for 15 minutes.

### b) Growth of the Silicon Nanowires (Process 1)

The pre-catalyst material obtained at the end of step a) is placed homogeneously in a mullite tube inside the fixed-bed reactor.

After connecting the gas line to the reactor and closing the heating chamber, the quartz tube is flushed with N₂ at 5 slm for several minutes to decrease the oxygen level. Subsequently, the reactor is heated up by means of the heating device placed in contact with the exterior surface of the quartz tube. The heating and gas injection cycles are as follows: a heating ramp of 1 h from 20° C. to 650° C. under 5 slm Ar/H₂ 2.5% gas flow rate, a plateau of 2.15 hours at 550° C. under 5 slm N₂/SiH₄ 0.9% (L/min), heating is stopped and then the reactor is cooled down to room temperature under 5 slm N₂ gas flow rate. The reactor is finally opened to recover the composite material.

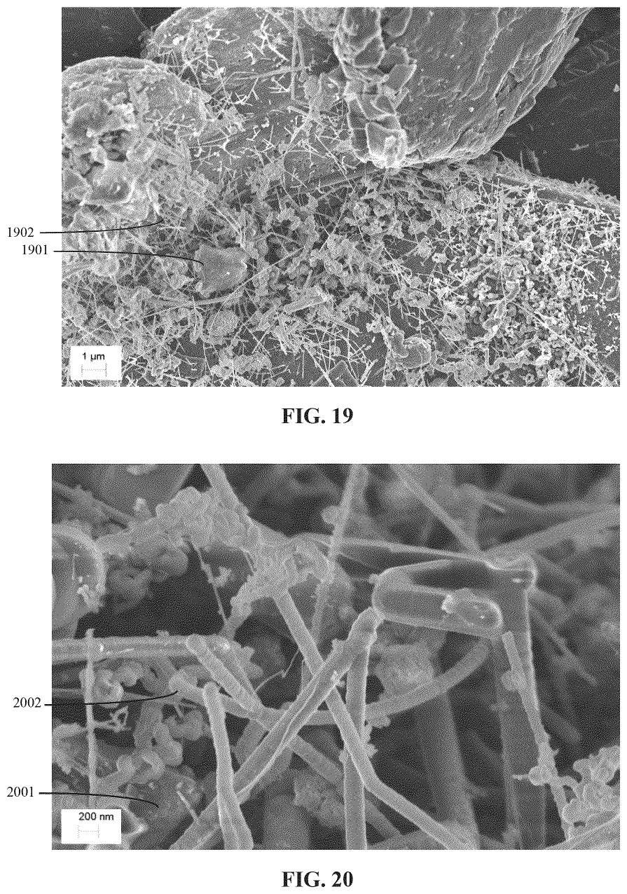

FIGS. 19 and 20 show SEM micrographs of the Si nanowires/copper CuCl/SFG75 graphite composite M7. The figures show straight and long Si NWs 1902 and 2002 having a mean diameter of 69 nm on the surface of the SFG75 graphite 1901 and 2001.

### Example 8: Preparation of the Electrodes for Lithium-Ion Batteries

The electrochemical characterization of materials M1, M2, M3, M2, M5, M4, M5, M6 and M7 was performed by preparing coin-cells wherein the anode comprises one of the prepared materials as active material.

a) Mixing with Conductive Fillers

The composite materials according to the invention M1, M2, M3, M2, M5, M4, M5, M6 and M7, were mixed with graphite powder using YSZ 3 mm diameter grinding balls, in an IKA® Ultra-Turrax Tube drive disperser.

The composite materials and the graphite were introduced into the disperser according to a weight ratio equal to 38:62.

Mixing was performed for 10 minutes at rotational speed 7.

The mixed material was finally recovered for further processing or characterization.

### b) Preparation of a Coin-Cell

Each synthesized material was mixed with graphite powder (Actilion GHDR-15-4 and SFG15 L) at a ratio of ca. 38:62. A reference graphite electrode was made using pure graphite as the active material to determine its gravimetric capacity. For both systems, carbon black C-NERGY C₆₅ was added as an electronic conductive additive, sodium carboxymethyl cellulose (Na-CMC) with styrene-butadiene rubber (SBR) were used as binders, and deionized water was employed as solvent. The weight ratios are 95:1:4 for the active material:C65:binders. Water was added to reach a viscosity allowing electrode processing, yielding to a dry content of about 40 wt %. Wet mixing was performed for 30 minutes at speed 5. Each electrode ink was cast on a copper foil of 20 μm. After drying in air, the electrodes were further dried at 65° C. in an oven for 2 hours. The electrodes were then cut into discs of 14 mm diameter, calendered at ca. 0.6 t/cm² and weighted, and were finally dried overnight in vacuum at 110° C.

Half coin-cells (Kanematsu KGK Corp®, stainless steel 316 L) were prepared inside an Ar glovebox using metallic Li as counter and reference electrodes, a layer of Whatman glass fiber and a layer of Celgard 2325 separator, and the electrode of interest. The electrolyte used to impregnate the electrode and separator materials was 1 M LiPF₆ dissolved in EC:DEC (1/1 v/v) with 10 wt % FEC (fluoroethylene carbonate) and 2 wt % VC (vinylene carbonate) additives. The cell was subsequently sealed with an automated press and taken out of the Ar glovebox to be measured on a battery cycler. Five formation cycles were performed prior to regular cycling at 1 C-rate. The formation cycles are made of 2 cycles at C/7 and 3 cycles at C/5 using galvanostatic and potentiostatic discharging (lithiation), and galvanostatic charging (delithiation).

### c) Determination of the Electrochemical Performances

The performances of the cells are determined by galvanostatic cycling using a Biologic BCS-805 cycling system equipped with 8 ways, each of the 8 ways comprising 2 different electrodes.

### 1—Potential Profile

The potential profile of the cells C1, C2, C3, C4, C5, C6 and C7, has been determined during the cycling at C/7 by measuring the potential of the cell as a function of its capacity.

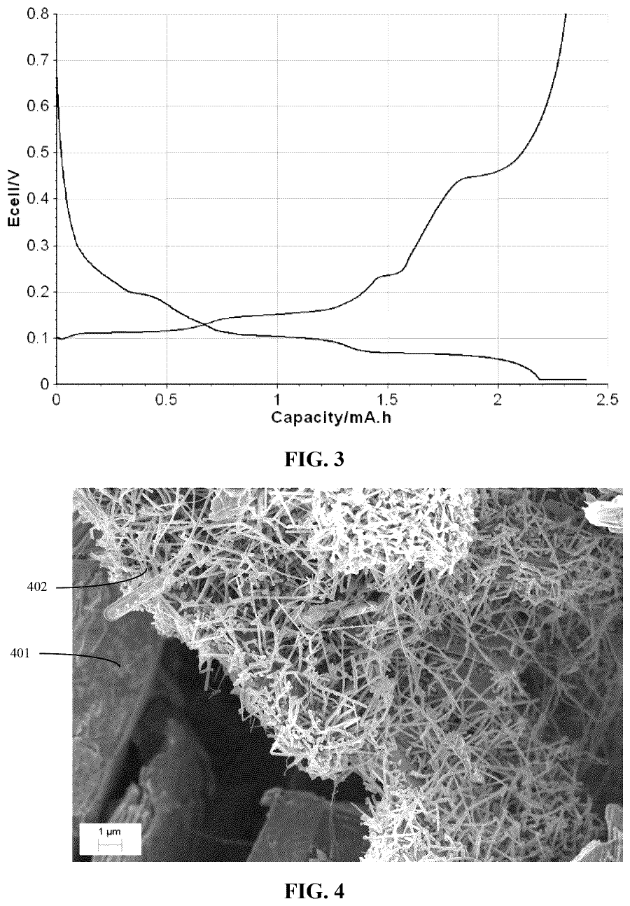

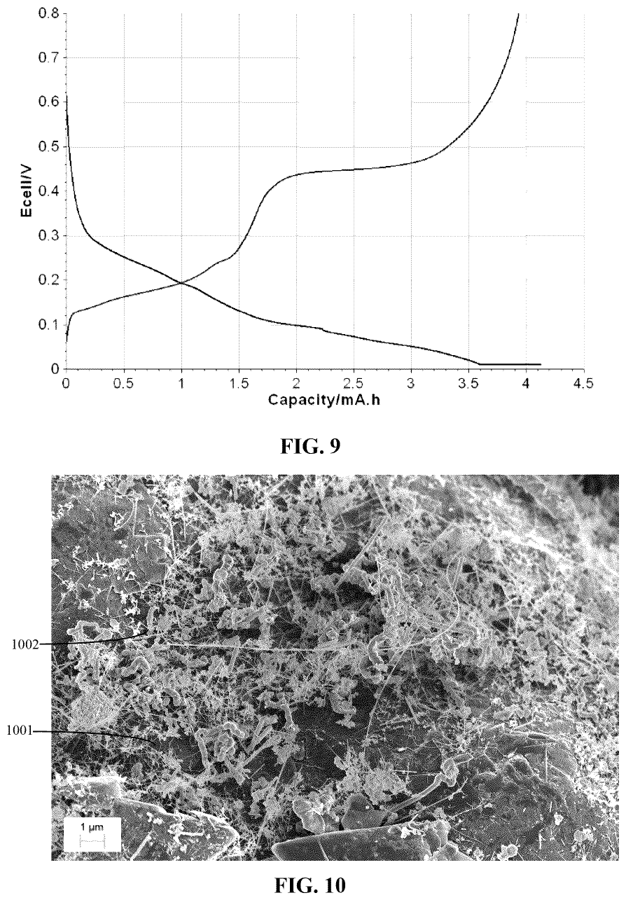

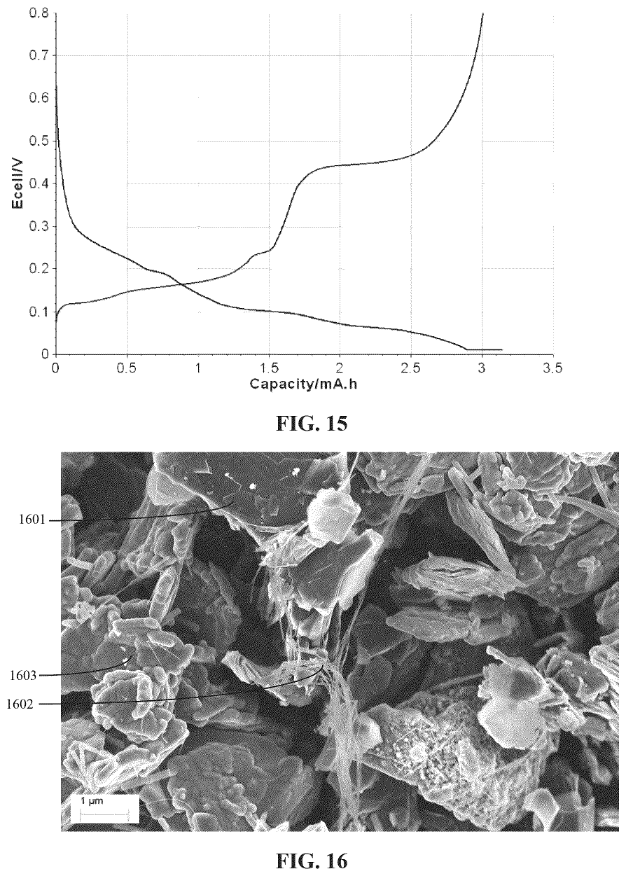

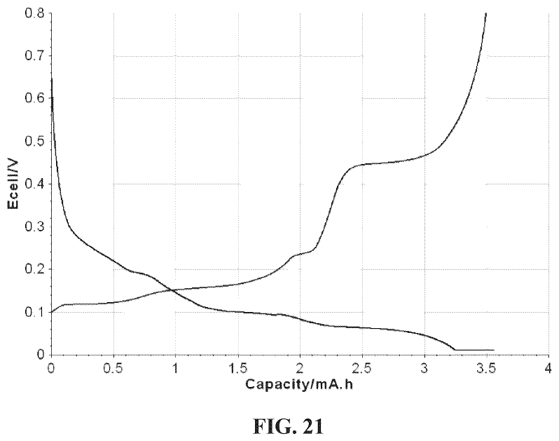

FIGS. 3, 6, 9, 12, 15, 18 and 21 represent the potential profiles obtained respectively from cells C1, C2, C3, C4, C5, C6 and C7, recorded during the second cycle at C/7.

On FIGS. 3, 6, 9 12, 15, 18 and 21, the potential profiles of the cells obtained from composite Materials M1, M2, M3, M2, M5, M4, M5, M6 and M7 respectively show the cumulation of the electrochemical activity of graphite (below 0.2 V) and silicon materials, which evidences that the composite materials are electrically and electrochemically active. The electrochemical activity of silicon with lithium ions is particularly highlighted by the inflexion/pseudo-plateau near 0.45 V during charge (delithiation).

### 2—Initial Reversible Capacity

The initial reversible capacity of the cells, measured at C/7 during the first cycle, is given in Table 2.

TABLE 2

| Cell | C1 | C2 | C3 | C4 | C5 | C6 | C7 |
|---|---|---|---|---|---|---|---|
| Initial capacity | 610 | 854 | 718 | 648 | 581 | 1081 | 677 |
| (mA · h/g) | | | | | | | |
| silicon active | 11.10 | 21.45 | 15.67 | 12.68 | 9.83 | 31.11 | 13.9 |
| content (wt %) | | | | | | | |

Cell C4, prepared from composite Material M4, and cell C7, prepared from composite Material M7, have similar initial reversible capacities. Therefore, composite Material M4 and composite Material M7 have the same silicon active content (ca. 12˜13%).

Moreover, a comparison of cells C1, C2, C3, C4, C5, C6, and C7 reveals an improvement of the initial capacity when the silicon active content increases.

Overall, these results demonstrate that the specific surface area and the morphology of the growth support permit to tune the form factor of Si NWs and allow to control of the electrical and electrochemical performances of the composite materials.

### REFERENCES

(1) D. Wolf et al., Energy Environ. Sci., 2016, 9, 1552-1576.
(2) X. Ou et al., ACS Appl. Mater. Interfaces, 2017, 9, 34527-34543.
(3) Y. Bando et al., Small, 2017, 13, 1701713.
(4) R. A. Huggins et al., J. Electrochem. Soc., 1981, 128, 725-729.
(5) L. L. Shaw et al., Nanoscale, 2016, 8, 74-103.
(6) Y. Cui et al., Nat. Nanotechnol., 2008, 3, 31-35.
(7) S. T. Lee et al., Nano Today, 2013, 8, 75-97.
(8) S. Sadki et al., Nanoscale Res. Lett., 2013, 8, 1-5.
(9) P. Yang et al. Nature, 2008, 451, 163-167.
(10) V. Schmidt et al., Chem. Rev. 2010, 110, 361-388.
(11) C. Y. Wen et al., Nano Lett. 2010, 10, 514-519.
(12) H. Y. Tuan et al., Chem. Mater. 2008, 20, 2306-2313.
(13) A. S. Hashimi et al., Current Applied Physics 2020, 20, 205-211.
(14) K. E. Korte et al., J. Mater. Chem. 2008, 18, 437-441.
(15) Dusanes et al., J Nanopart Res, 2020, 22, 363.

1. A method for the preparation of a composite material comprising at least silicon nanowires and copper, comprising at least the following stages:
(A) introducing into the chamber of a reactor a solid/solid mixture of at least
a copper halide CuXₙ, with X being selected from: F, Cl, Br, I, and n being an integer selected from 1 or 2,
a growth support in powder form,
(B) growing silicon nanowires in the chamber of the reactor, from at least one precursor compound of the silicon nanowires selected from a silane compound or a mixture of silane compounds,
and
(C) recovering the product.

2. The method as claimed in claim 1, wherein step (A) comprises:
(1) solid/solid mixing of at least:
a copper halide CuXₙ, with X being selected from: F, Cl, Br, I, and n being an integer selected from 1 or 2,
a growth support in powder form,
(2) introducing into a chamber of a reactor the mixture obtained at step (1),
Or
(1′) introducing into a chamber of a reactor at least:
a copper halide CuXₙ, with X being selected from: F, Cl, Br, I, and n being an integer selected from 1 or 2,
a growth support in powder form,
(2′) solid/solid mixing the copper halide and the growth support in the chamber of the reactor.

3. The method as claimed in claim 1, wherein step (B) comprises:
(3) introducing, into the chamber of the reactor, at least one precursor compound of the silicon nanowires chosen from a silane compound or a mixture of silane compounds,
(4) decreasing the dioxygen content in the chamber of the reactor,
(5) applying a thermal treatment at a temperature ranging from 200° C. to 900° C.,
wherein the order of steps (3) to (5) can be the recited order or another order.

4. The method as claimed in claim 1, wherein it is implemented in a fixed-bed reactor, in the tubular chamber of a tumbler reactor set in motion by a rotating and/or a mixing mechanism or in a vertical fluidized bed reactor.

5. The method as claimed in claim 1, wherein the growth support is selected from carbon-based materials and carbonaceous polymers.

6. The method as claimed in claim 5, wherein the carbon-based material is selected from carbon black nanoparticles, carbonaceous polymer fibers, carbon nanotubes, graphene and graphite.

7-13. (canceled)

14. The method as claimed in claim 6, wherein the carbon-based material has a mean particle size from 0.01 μm to 100 μm.

15. The method as claimed in claim 1, wherein the growth support is selected from silicon nanoparticles or silicon microparticles.

16. The method as claimed in claim 1, wherein the copper halide and the growth support material are used in a mass ratio copper halide/growth support ranging from 0.01 to 1.

17. The method as claimed in claim 1, wherein the copper halide is used as raw material.

18. The method as claimed in claim 17, wherein the copper halide is in powder form.

19. The method as claimed in claim 1, wherein the copper halide is selected from the group consisting of copper (I) chloride CuCl, copper (II) chloride CuCl₂, and a mixture thereof.

20. The method as claimed in claim 1, wherein the precursor compound of the silicon nanowires is silane (SiH₄) or diphenylsilane Si(C₆H₅)₂H₂.

21. The method as claimed in claim 1, wherein the thermal treatment is performed at a temperature ranging from 300° C. to 700° C.

22. The method as claimed in claim 1, wherein the thermal treatment is applied from 1 minute to 10 hours.

23. The method as claimed in claim 1 further comprising a post-treatment step in order to transform organics resulting from the precursor compound of the silicon nanowires into carbon materials.

24. The method as claimed in claim 1, further comprising an additional step of washing the composite material obtained at the end of step (C).

25. The method as claimed in claim 1, further comprising the introduction, into the reactor, of at least one doping material.

26. A method of making an electrode including a current collector, said method comprising (i) implementing the method of claim 1 to prepare a composite material and (ii) covering at least one surface of the current collector with a composition comprising said silicon-copper composite material as an electrode active material.

27. A method of making an energy storage device including a cathode, an anode, and a separator disposed between the cathode and the anode, wherein said method comprises implementing the method of claim 26 to make at least one of the electrodes.
